(19) United States
(12) Patent Application Publication
(10) Pub. No.: US 2013/0153852 A1
(43) Pub. Date: Jun. 20, 2013

(54) VARIABLE RESISTANCE MEMORY DEVICES AND METHODS OF FORMING THE SAME

(71) Applicants: Jintaek Park, Gyeonggi-do (KR); Youngwoo Park, Seoul (KR)

(72) Inventors: Jintaek Park, Gyeonggi-do (KR); Youngwoo Park, Seoul (KR)

(21) Appl. No.: 13/690,575

(22) Filed: Nov. 30, 2012

(30) Foreign Application Priority Data
Dec. 20, 2011 (KR) 10-2011-0138295

(51) Int. Cl. H01L 45/00

(52) U.S. Cl. CPC H01L 45/04
USPC 257/4

(57) ABSTRACT

A variable resistance memory device comprises a bit line extended in a first direction, a vertical electrode extended vertically in a third direction and configured to be vertically aligned with the bit line in the third direction, a variable resistance layer disposed on a part of the vertical electrode, multiple word lines disposed on the variable resistance layer and stacked in the third direction, wherein each of multiple word lines are extended in a second direction, and a selection transistor including a first dopant injection region electrically connected to the vertical electrode, and a second dopant injection region electrically connected to the bit line.

### CROSS-REFERENCE TO RELATED APPLICATIONS

This U.S. non-provisional patent application claims priority under 35 U.S.C. §119 to Korean Patent Application No. 10-2011-0138295, filed on Dec. 20, 2011, the disclosure of which is hereby incorporated by reference in its entirety.

### TECHNICAL FIELD

The inventive concept relates to variable resistance memory devices and methods of forming the same.

### DISCUSSION OF THE RELATED ART

In response to the increased demand for high speed nonvolatile memory devices, new semiconductor memory devices such as ferroelectric random access memories (FRAMs), a magnetic random access memories (MRAMs), and a phase-change random access memories (PRAMs) have been developed. Such semiconductor devices have memory cells whose resistance values change according to a current or a voltage applied. These memory cells have a non-volatile memory property because they maintain their resistance values when the current supply or the voltage supply is interrupted.

As semiconductor devices become highly integrated, the variable resistance memory devices also become more and more highly integrated.

### SUMMARY

In an embodiment, a variable resistance memory device comprises a bit line extended in a first direction, a vertical electrode extended vertically in a third direction and configured to be vertically aligned with the bit line in the third direction, a variable resistance layer disposed on a part of the vertical electrode, multiple word lines disposed on the variable resistance layer and stacked in the third direction, wherein each of multiple word lines are extended in a second direction, and a selection transistor including a first dopant injection region electrically connected to the vertical electrode, and a second dopant injection region electrically connected to the bit line.

In an embodiment, the variable resistance memory device further comprises an active pattern disposed over the bit line, wherein the first dopant injection region and the second dopant injection region are disposed in the active pattern and the active pattern dispose over the bit line, and a bit line node contact disposed on the bit line, being electrically connected with the second dopant injection region. The bit line node contact is configured to penetrate the active pattern and has a top surface substantially coplanar with a top surface of the active pattern. Alternatively, the bit line node contact is configured to contact with a bottom surface of the active pattern.

In an embodiment, the variable resistance memory device includes a vertical electrode having a first sub-vertical electrode disposed on the first dopant injection region, a first pad disposed on the first sub-vertical electrode and a second sub-vertical electrode disposed on the pad. The variable resistance memory device further comprise a second pad being disposed over the bit line node contact wherein the second pad is disposed over the bit line node and the second pad has a line shape extended in the first direction.

In an embodiment, the variable resistance memory device further comprises a peripheral circuit disposed under the vertical electrode and the bit line, wherein the peripheral circuit controls voltages applied to the word lines, the bit line, and the selection transistor. End portions of the word lines constitute a stepped structure. Each of the multiple word lines includes two groups of word lines on a same cell layer and each group of word lines includes a plurality of word lines connected to each other. The selection transistor includes a gate electrode having a line-shape extended in the first direction in a plan view and being disposed over the bit line.

In an embodiment, the first dopant injection region includes a first low-concentration dopant injection region adjacent to one side of the gate electrode and a first high-concentration dopant injection region separated from the one side of the gate electrode. The second dopant injection region includes a second low-concentration dopant injection region adjacent to another side of the gate electrode and a second high-concentration dopant injection region separated from the another side of the gate electrode.

In an embodiment, a method of manufacturing a variable resistance memory device comprises a step of forming a bit line extended in a first direction, forming a vertical electrode extended vertically in a third direction, wherein the vertical electrode is disposed over a part of the bit line vertically, a step of forming a variable resistance layer on a part of the vertical electrode, and a step of forming multiple word lines on the variable resistance layer, wherein the multiple word lines are stacked vertically and each of multiple word lines are extended in a second direction, and a step of forming a selection transistor including a first dopant injection region electrically connected to the vertical electrode, and a second dopant injection region electrically connected to the bit line.

In an embodiment, the method further comprise a step of forming an active pattern over the bit line, wherein the first dopant injection region and the second dopant injection region are disposed in the active pattern and the active pattern is disposed on the bit line vertically and a step of forming a bit line node contact on the bit line wherein the bit line node is electrically connected with the second dopant injection region.

Alternatively, the method further comprises a step of forming an active pattern under the bit line, wherein the first dopant injection region and the second injection region are disposed in the active pattern and the active pattern is disposed over the bit line, and a step of forming a bit line node contact on the second dopant injection region, wherein the bit line node contact is electrically connected with the bit line.

In an embodiment, the method further comprises a step of forming a peripheral circuit under the vertical electrode and the bit line, wherein the peripheral circuit controls voltages applied to the word lines, the bit line, and the selection transistor.

In an embodiment, the variable resistance memory device comprises an active pattern disposed under the bit line, wherein the first dopant injection region and the second injection region are disposed in the active pattern and the active pattern is disposed over the bit line, and a bit line node contact disposed on second injection region, electrically being connected with the bit line.

In an embodiment, the active pattern is disposed over the multiple word lines and the vertical electrode includes a first sub-vertical electrode penetrating the first dopant injection region and a second sub-vertical electrode disposed on the first sub-vertical electrode and adjacent to the multiple word lines.

In an embodiment, the first and second dopant injection regions are disposed in a substrate. The bit line node contact includes a first bit line node contact disposed on the second dopant injection region and a second bit line node contact disposed on the first bit line node contact disposed on the bit line, and a second pad connecting the first bit line node and the second bit line node.

In an embodiment, the multiple word lines are disposed between the bit line and the active pattern, and the bit line node contact includes a first bit line node contact disposed on the second dopant injection region, a second bit line node contact disposed on the first bit line node contact disposed on the bit line, and a second pad connecting the first bit line node and the second bit line node.

### BRIEF DESCRIPTION OF THE DRAWINGS

The inventive concept will become more apparent in view of the attached drawings and accompanying detailed description.

FIG. 1 is a schematic circuit diagram illustrating a variable resistance memory device according to an embodiment of the inventive concept;

FIG. 2A is a layout illustrating a variable resistance memory device according to an embodiment of the inventive concept;

FIG. 2B is a cross-sectional view taken along a line I-I′ of FIG. 2A to illustrate a variable resistance memory device of FIG. 2A;

FIG. 2C is a cross-sectional view taken along a line II-II′ of FIG. 2A to illustrate a variable resistance memory device of FIG. 2A;

FIGS. 3A, 4A, 5A, 6A, 7A, 8A, 9A, and 10A are plan views illustrating a method of forming a variable resistance memory device of FIG. 2A;

FIGS. 3B, 4B, 5B, 6B, 7B, 7C, 8B, 9B, 10B, 10C, and 10D are cross-sectional views taken along lines I-I′ of FIGS. 3A, 4A, 5A, 6A, 7A, 8A, 9A, and 10A to illustrate a method of forming a variable resistance memory device of FIG. 2B;

FIG. 11 is a cross-sectional view illustrating a variable resistance memory device according to an embodiment of the inventive concept;

FIG. 12 is a cross-sectional view illustrating a variable resistance memory device according to an embodiment of the inventive concept;

FIG. 13 is a cross-sectional view illustrating a variable resistance memory device according to an embodiment of the inventive concept;

FIGS. 14A and 14B are a cross-sectional view illustrating a variable resistance memory device according to an embodiment of the inventive concept;

FIG. 15 is a cross-sectional view illustrating a variable resistance memory device according to an embodiment of the inventive concept;

FIG. 16 is a schematic block diagram illustrating a memory card including a memory device according to embodiments of the inventive concept; and

FIG. 17 is a schematic block diagram illustrating an information processing system including a variable resistance memory device according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Hereinafter, embodiments of the inventive concept will be described in more detail with reference to the drawings.

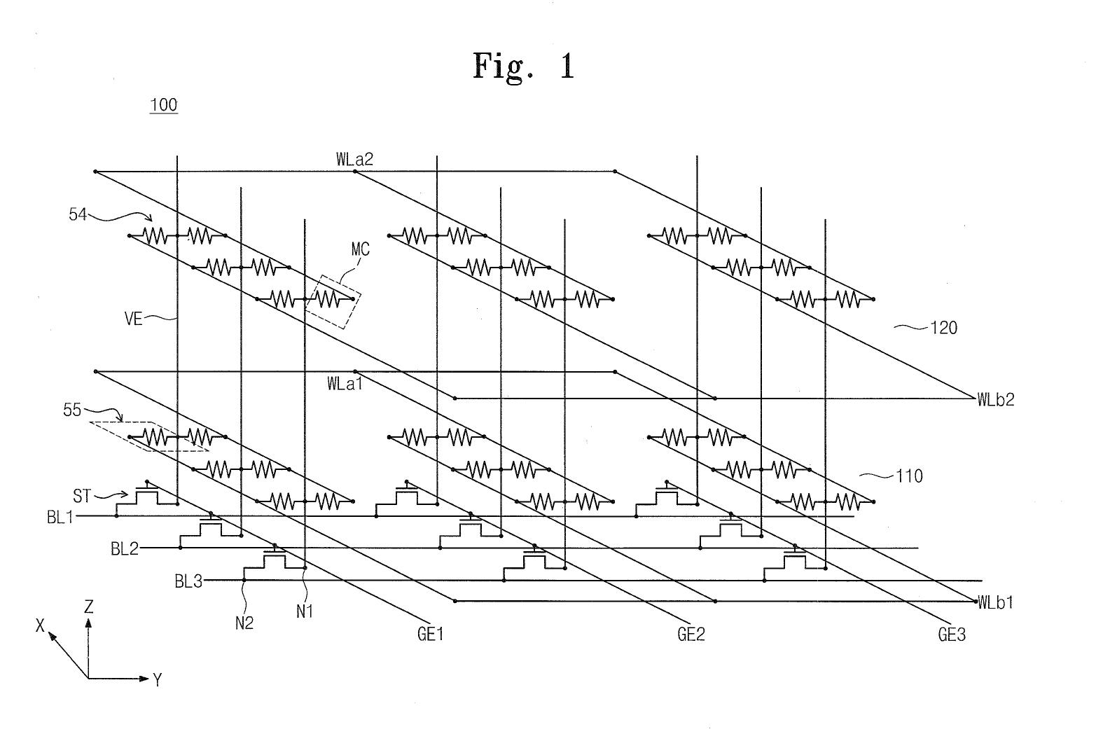

FIG. 1 is a schematic circuit diagram illustrating a variable resistance memory device according to an embodiment of the inventive concept.

Referring to FIG. 1, the variable resistance memory device 100 includes a plurality of memory cells MC arranged in a three-dimensional matrix form. For simplicity of explanation, assume that the memory cells MC are disposed in two cell layers 110 and 120 although additional layers may also be present. Each of the memory cells MC includes a variable resistance element 54.

The variable resistance element 54 is connected between a selection transistor ST and a word line WLb2 of word lines WLa1, WLb1, WLa2, and WLb2. The word line WLb2 may be extended in a first direction X. For example, the variable resistance element 54 may include one of phase-change materials, transition metal oxides, ferroelectric materials, and magnetic materials. The variable resistance memory device 100 may be applied to a phase-change random access memory (PRAM) device, a resistance random access memory (RRAM) device, a ferroelectric random access memory (FRAM) device, or a magnetic random access memory (MRAM) device, depending on the material kind of the variable resistance element 54. The variable resistance element 54 may have at least two possible states per cell depending on the amount of a current supplied through the selection transistor ST.

The selection transistor ST is connected between the variable resistance element 54 and a bit line BL1 of bit lines BL1, BL2, and BL3. The bit line BL1 may be extended in a second direction Y. The selection transistor ST includes a gate electrode GE1 of gate electrodes GE1, GE2, or GE3. The selection transistor ST includes a first node N1 connected to the variable resistance element 54 and a second node N2 connected to the bit line BL1.

A vertical electrode VE is connected to the first node N1. The vertical electrode VE may be extended in a third direction Z. The first, second, and third directions X, Y, and Z are perpendicular to each other. For simplicity of explanation, the vertical electrode VE has two variable resistance elements 54 and 55 disposed one over the other. A plurality of the variable resistance elements may be connected to one vertical electrode VE and are disposed one over the other, forming a plurality of cell layers. In other words, a plurality of the variable resistance elements are connected to one selection transistor ST.

The word lines WLa1, WLb1, WLa2, and WLb2 may be disposed throughout the two cell layers 110 and 120 and be parallel to each other. Each cell layer has two groups of word lines. The first group of word lines WLa1 of the first cell layer 110 may be connected to each other. The second group of word lines WLb1 of the first cell layer 110 may be connected to each other and be insulated from the first group of word lines WLa1. The first group of word lines WLa2 of the second cell layer 120 may be connected to each other. The second group of word lines WLb2 of the second cell layer 120 may be connected to each other and be insulated from the first group of word lines WLa2.

According to this embodiment of the inventive concept, the variable resistance memory device includes the bit lines BL1, BL2, and BL3 vertically overlapped with the vertical electrodes VE. In other words, the bit lines BL1, BL2, and BL3 may be disposed at a level different from the vertical electrodes VE. The bit lines BL1, BL2, and BL3 may be disposed to be vertically overlapped with the vertical electrodes VE. Thus, the variable resistance memory device may reduce the planar area necessary for forming the bit lines, resulting in higher integration density. Additionally, since the memory cells are three-dimensionally arranged over a plurality of cell layers, a planar area of the variable resistance memory device may be reduced.

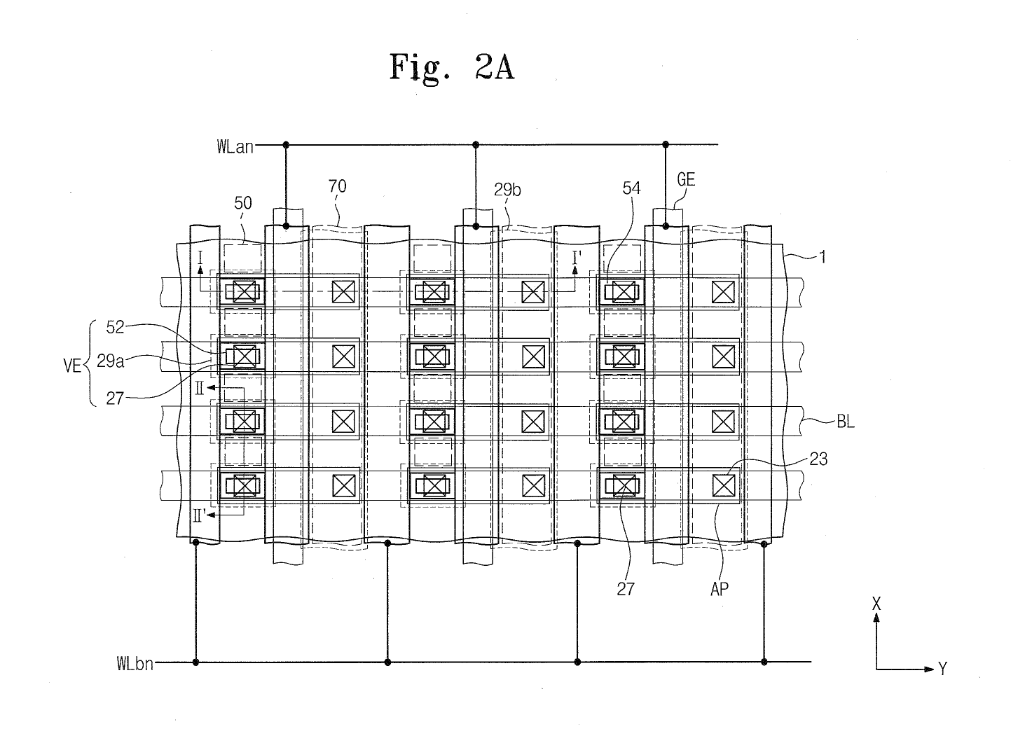

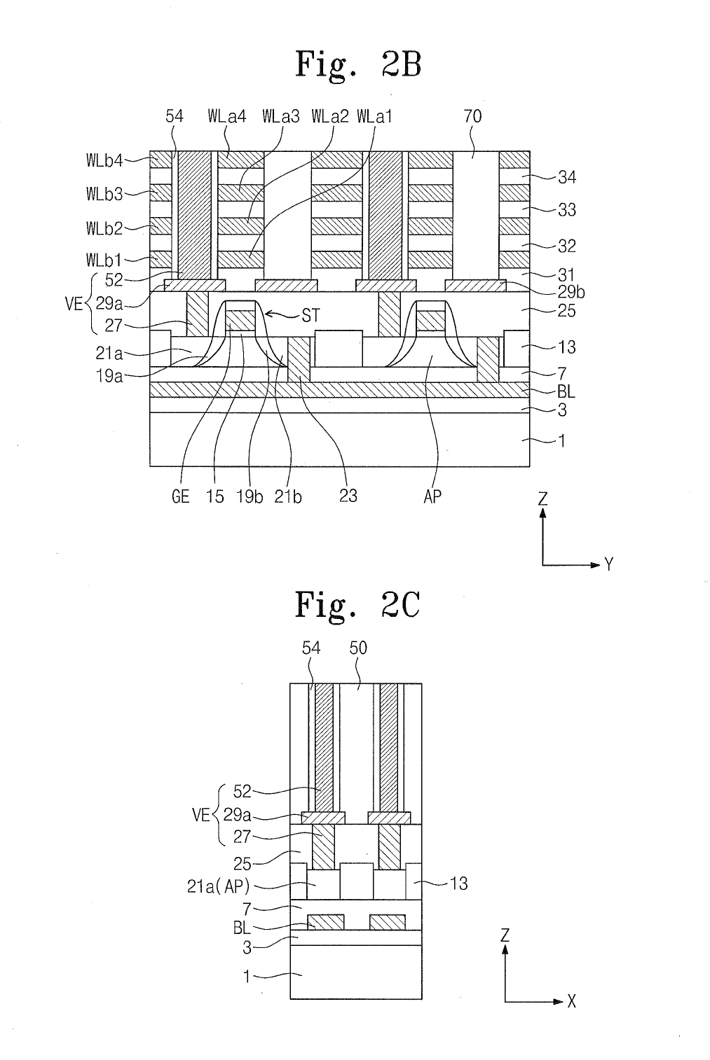

FIG. 2A is a layout illustrating a variable resistance memory device according to an embodiment of the inventive concept. FIG. 2B is a cross-sectional view taken along a line I-I′ of FIG. 2A. FIG. 2C is a cross-sectional view taken along a line II-II′ of FIG. 2A.

Referring to FIGS. 2A, 2B, and 2C, a first insulating layer 3 may be disposed on a substrate 1. A plurality of bit lines BL may be disposed on the first insulating layer 3. The plurality of bit lines BL may be parallel to each other and be spaced apart from each other. The bit lines BL may include a conductive material. The bit lines BL may be extended in the second direction Y. A second insulating layer 7 may be disposed on the bit lines BL. The second insulating layer 7 may be disposed on the bit lines BL. A plurality of active patterns AP may be disposed on the second insulating layer 7. The active patterns AP are spaced apart from each other. Each of the active patterns AP may have a bar-shape on the layout of FIG. 2A. The active patterns AP may be spaced apart from each other by a device isolation layer 13. Each of the active patterns AP may include a single-crystalline semiconductor material.

Gate electrodes GE may be disposed on the active patterns AP with a gate insulating layer 15 therebetween. First dopant injection regions 19a and 21a and second injection regions 19b and 21b may be disposed in the active patterns AP at either side of the gate electrodes GE. The first dopant injection regions 19a and 21 a may include first low-concentration dopant injection regions 19a adjacent to one side of the gate electrodes GE and first high-concentration dopant injection regions 21a separated from the one side of the gate electrodes GE. The second dopant injection regions 19b and 21b may include second low-concentration dopant injection regions 19b adjacent to the other side of the gate electrodes GE and second high-concentration dopant injection regions 21b separated from the other side of the gate electrodes GE. A capping layer may be disposed on the gate electrodes GE. Spacers may be disposed on sidewalls of the gate electrodes GE, respectively. The gate electrodes GE, the gate insulating layer 15, and the first and second dopant injection regions 19a, 21a, 19b, and 21b may constitute selection transistors ST. The gate electrodes GE may be extended in the first direction X on a plurality of the active patterns AP. Since the selection transistors ST includes the first and second low-concentration dopant injection regions 19a and 19b, a short channel effect characteristic of the selection transistors ST may be improved. Bit line node contacts 23 may penetrate the second insulating layer 7, connecting the second high-concentration dopant injection regions 21b to the bit lines BL. The bit line node contacts 23 may be extended to penetrate the active patterns AP. The bit line node contacts 23 may have a top surface substantially coplanar with a top surface of the active patterns AP. The bit line node contacts 23 may include a conductive material.

A third insulating layer 25 covers the gate electrodes GE and the active patterns AP. The third insulating layer 35 may have a flat top surface. The first, second, and third insulating layers 3, 7, and 25 may include at least one of a silicon oxide layer, a silicon nitride layer, and a silicon oxynitride layer. First sub-vertical electrodes 27 may penetrate the third insulating layer 25, contacting with the first high-concentration dopant injection regions 21a. First pads 29a and second pads 29b may be disposed on the third insulating layer 25. The first pads 29a and the second pads 29b are laterally spaced apart from each other. The first pads 29a and the second pads 29b are alternately arranged. The first and second pads 29a and 29b may include a conductive material. The first pads 29a are in contact with the first sub-vertical electrodes 27. The first pads 29a may have an island-shape. A plurality of the first pads 29a may be arranged in the first direction X. The second pads 29b may have a line-shape extended in the first direction X.

A first word line-interlayer insulating layer 31 is disposed on the first and second pads 29a and 29b. A plurality of cell layers of word lines WLan and WLbn of FIG. 2A (where n is a cell layer number) may be disposed at either side of second sub-vertical electrodes 52 on the first word line-interlayer insulating layer 31. For simplicity of explanation, the word lines WLan and WLbn are disposed over four cell layers. As illustrated in FIG. 2B, first to fourth word lines WLa1, WLb1, WLa2, WLb2, WLa3, WLb3, WLa4, and WLb4 may be sequentially stacked on the first word line-interlayer insulating layer 31. Second to fourth word line-interlayer insulating layers 32, 33, and 34 may be disposed between the first to fourth word lines WLa1, WLb1, WLa2, WLb2, WLa3, WLb3, WLa4, and WLb4. The first to fourth word lines WLa1, WLb1, WLa2, WLb2, WLa3, WLb3, WLa4, and WLb4 may include first to fourth first group word lines WLa1, WLa2, WLa3, and WLa4, respectively. Additionally, the first to fourth word lines WLa1, WLb1, WLa2, WLb2, WLa3, WLb3, WLa4, and WLb4 may include first to fourth second group word lines WLb1, WLb2, WLb3, and WLb4, respectively. In other words, the first word lines WLa1 and WLb1 are disposed in the first cell layer and include the first group word lines WLa1 and the second group word lines WLb1 which are laterally arranged. The second word lines WLa2 and WLb2 disposed in the second cell layer may include the first group word lines WLa2 and the second group word lines WLb2 which are laterally arranged. The third word lines WLa3 and WLb3 disposed in the third cell layer may include the first group word lines WLa3 and the second group word lines WLb3 which are laterally arranged. The fourth word lines WLa4 and WLb4 disposed in the fourth floor may include the first group word lines WLa4 and the second group word lines WLb4 which are laterally arranged. The odd-numbered word lines WLan of each cell layer are electrically connected to each other. The even-numbered word lines WLbn of each cell layer are electrically connected to each other, and are insulated from the odd-numbered word lines WLan in the same cell layer. Additionally, the word lines of each cell layer are insulated from the word lines of another cell layer. For example, the second group word lines WLb2 of the second cell layer are insulated from the second group word lines of both the first and third cell layers.

Vertical electrodes VE include second sub-vertical electrodes 52, the first pads 29a and the first sub-vertical electrodes 27. The vertical electrodes VE are aligned vertically with the bit lines BL and disposed over the bit lines BL. Second sub-vertical electrodes 52 are disposed on the first pads 29a. Variable resistance layers 54 are disposed on the second sub-vertical electrodes 52. The word lines WLa1, WLb1, WLa2, WLb2, WLa3, WLb3, WLa4, and WLb4 are disposed on the variable resistance layers 54. The variable resistance layer 54 may include one of phase-change materials, transition metal oxides, ferroelectric materials, and magnetic materials. The variable resistance memory device according to embodiments may be applied to a PRAM device, a RRAM device, a FRAM device, or a MRAM device, depending on the material kind of the variable resistance layer 54.

Referring to FIGS. 2A and 2C, a first filling insulating layer 50 may be disposed between the second sub-vertical electrodes 52 adjacent to each other in the first direction X. The variable resistance layers 54 may be configured to be interposed between the first filling insulating layer 50 and the second sub-vertical electrodes 52. A second filling insulating layer 70 may be disposed between the second sub-vertical electrodes 52 neighboring to each other in the second direction Y.

Referring to FIGS. 2A and 2B, the second filling insulating layers 70 are spaced apart from the second sub-vertical electrodes 52. The second filling insulating layers 70 have a line-shape extended in the first direction X and separate the word lines WLan and WLbn from each other. The second filling insulating layer 70 is in contact with the second pad 29b.

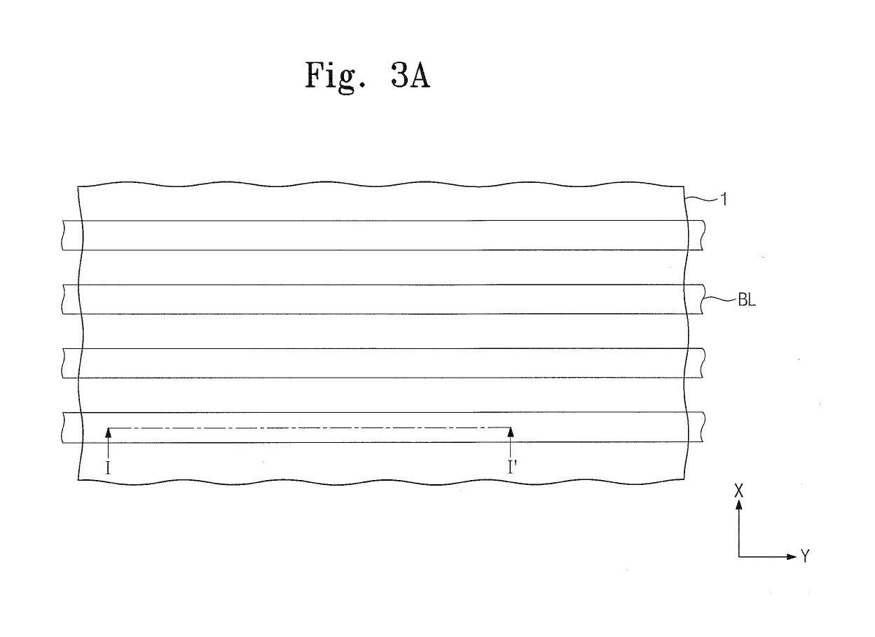

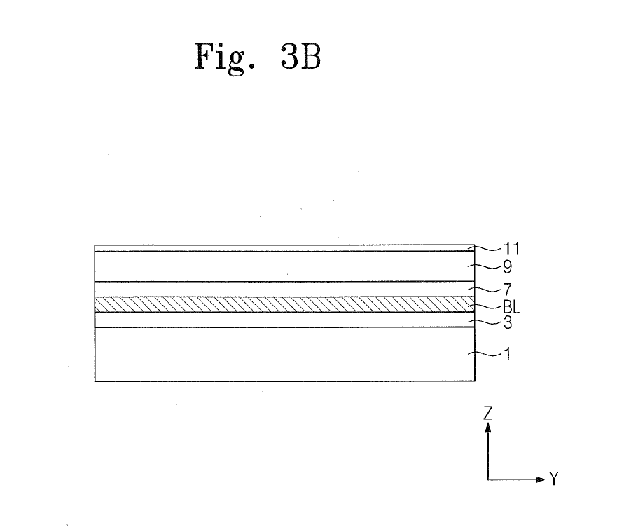

Next, a method of forming the variable resistance memory device of FIGS. 2A to 2C will be described with reference to the drawings. FIGS. 3A, 4A, 5A, 6A, 7A, 8A, 9A, and 10A are plan views illustrating a method of forming the variable resistance memory device of FIG. 2A. FIGS. 3B, 4B, 5B, 6B, 7B, 7C, 8B, 9B, 10B, 10C, and 10D are cross-sectional views taken along lines I-I′ of FIGS. 3A, 4A, 5A, 6A, 7A, 8A, 9A, and 10A to illustrate a method of forming the variable resistance memory device of FIG. 2B.

Referring to FIGS. 3A and 3B, a first insulating layer 3 may be formed on an entire surface of a substrate 1. The substrate 1 may be a single-crystalline silicon substrate, a silicon-on-insulator (SOI), or a silicon epitaxial layer. A plurality of bit lines BL parallel to each other may be formed on the first insulating layer 3. After a conductive layer (not shown here) is formed and the conductive layer is etched using a mask, thereby forming the bit lines BL. Alternatively, the bit lines BL may be formed by a damascene method. The bit lines BL may be extended in the second direction Y. A second insulating layer 7 may be formed on the bit lines BL. The second insulating layer 7 may cover the top surfaces and the sidewalls of the bit lines BL. The second insulating layer 7 may be planarized. An active layer 9 may be formed on the second insulating layer 7. The active layer 9 may be formed of a poly-silicon layer or a single-crystalline semiconductor layer. The active layer 9 may be formed by a selective epitaxial growth (SEG) method or a laser epitaxial growth (LEG) method. The active layer 9 may be doped with, for example, P-type dopants. A buffer layer 11 may be formed on the active layer 9.

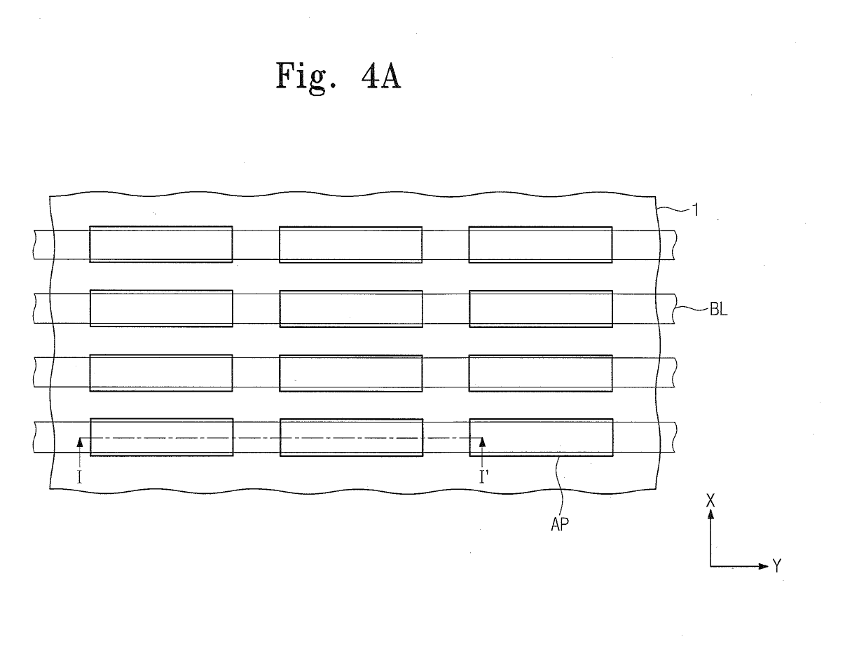

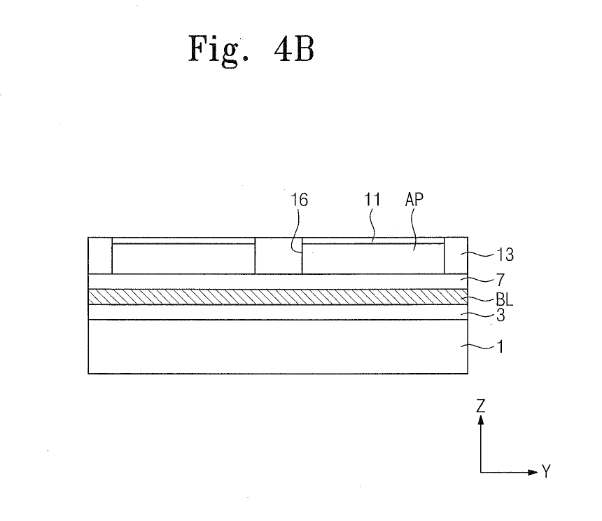

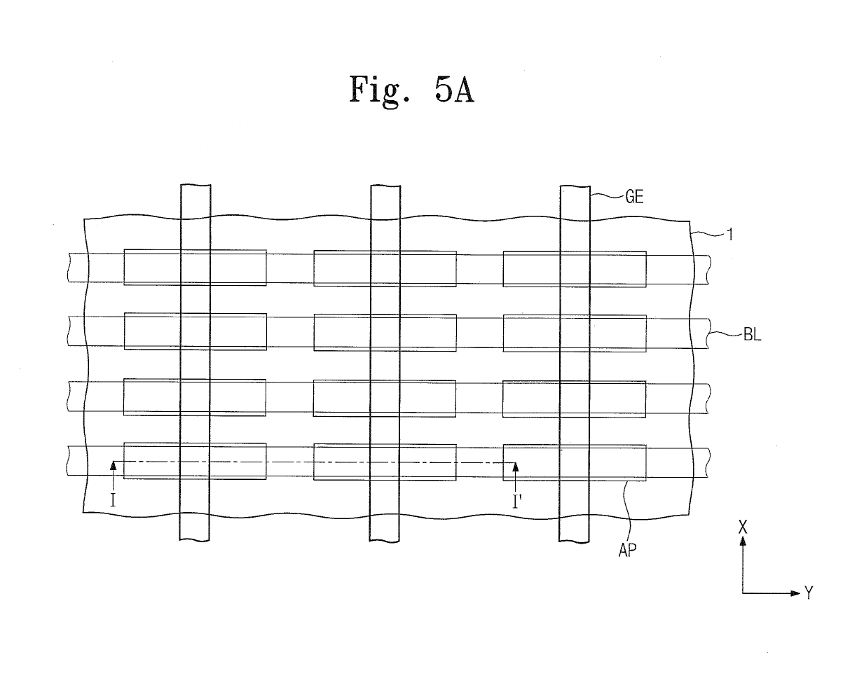

Referring to FIGS. 4A and 4B, the buffer layer 11 and the active layer 9 may be etched to form trenches 16. The trenches 16 are formed between active patterns AP exposing the second insulating layer 7. The trench may be filled with an insulating layer (not shown here), thereby forming a device isolation layer 13. The device isolation layer 13 may have a mesh-shape, surrounding the active patterns AP. Each of active patterns AP may be isolated from each other by the device isolation layer 13. Each of the active patterns AP may have a bar-shape extended in the second direction Y in a plan view.

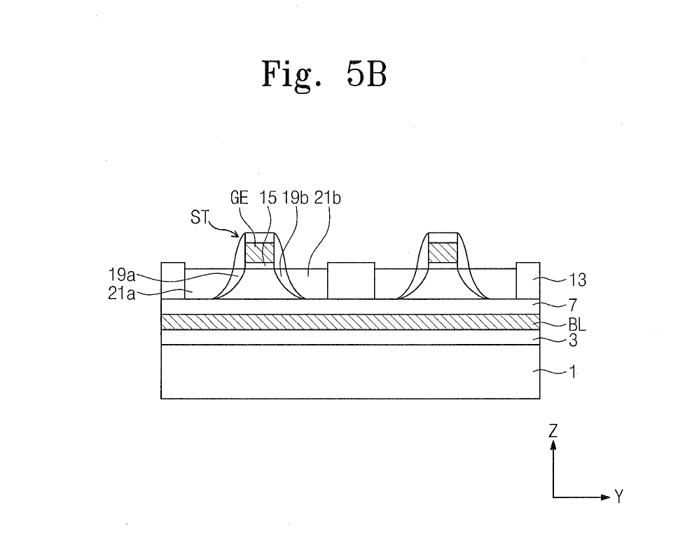

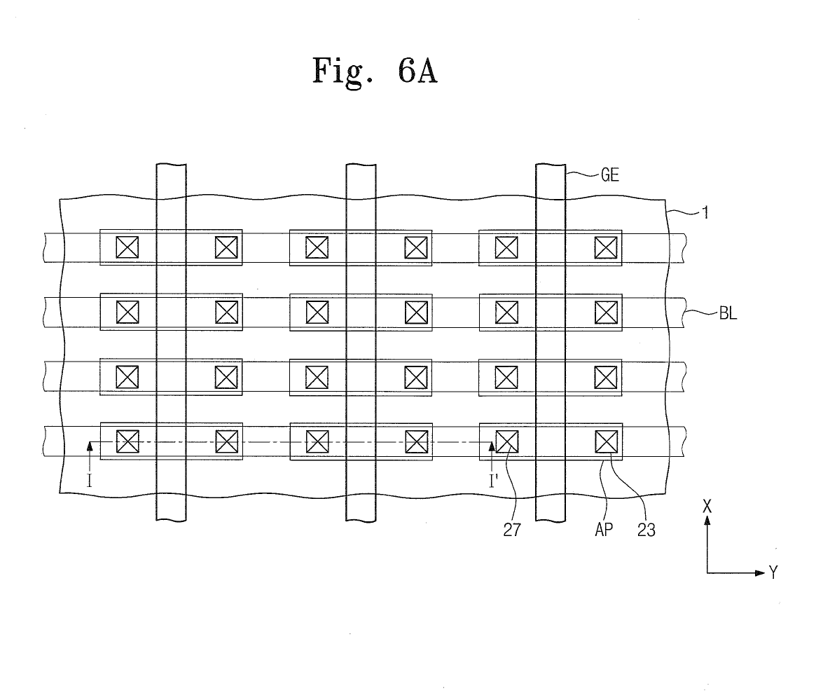

Referring to FIGS. 5A and 5B, selection transistors ST may be formed at the active patterns AP. After the buffer layer 11 is removed, a gate insulating layer 15 may be formed on the active pattern AP. A conductive layer and a capping layer may be sequentially formed on the gate insulating layer 15 and then the capping layer and the conductive layer may be patterned to form gate electrodes GE. The gate electrodes GE may have a line-shape extended in the first direction X and may be disposed on the active patterns AP arranged in the first direction X. First and second low-concentration dopant injection regions 19a and 19b may be formed in the active patterns AP by a first ion implantation process using the gate electrodes GE and the capping layer on the gate electrode as ion implantation masks. Subsequently, after spacers covering the sidewalls of the gate electrodes GE are formed, a second ion implantation process may be performed to form first and second high-concentration dopant injection regions 21a and 21b in the active patterns AP. Thus, the selection transistors ST may be formed.

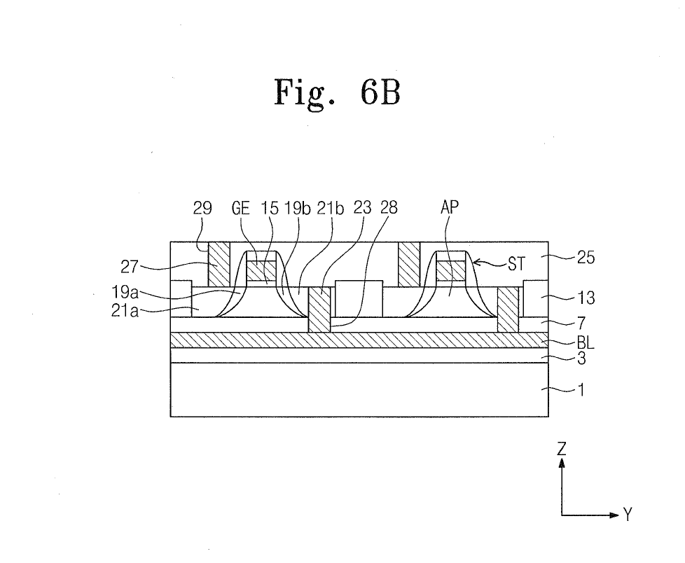

Referring to FIGS. 6A and 6B, the active patterns AP of the second high-concentration dopant injection regions 21b and the second insulating layer 7 thereunder may be etched using a predetermined mask to form bit line node holes 28 exposing the bit lines BL. A conductive layer may be formed to fill the bit line node hole and then the conductive layer may be recessed to form bit line node contacts 23. Subsequently, a third insulating layer 25 may be formed to cover the active patterns AP and the gate electrodes GE. The top surface of the third insulating layer 25 may be formed to be substantially flat. The third insulating layer 25 may be etched to form a hole 29 exposing the top surface of the first high-concentration dopant injection region 21 a and then the hole 29 is filled with a conductive layer to form first sub-vertical electrodes 27.

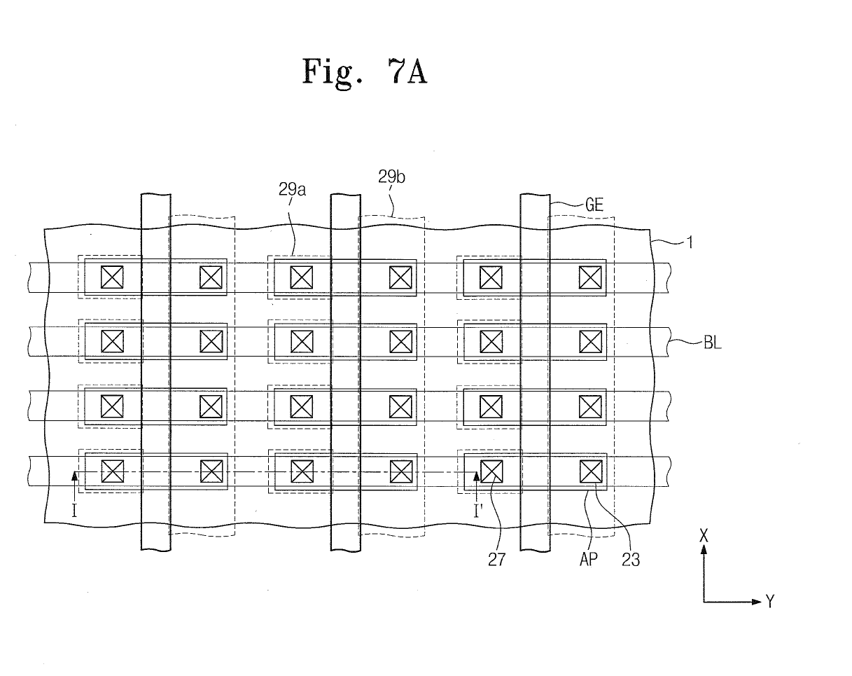

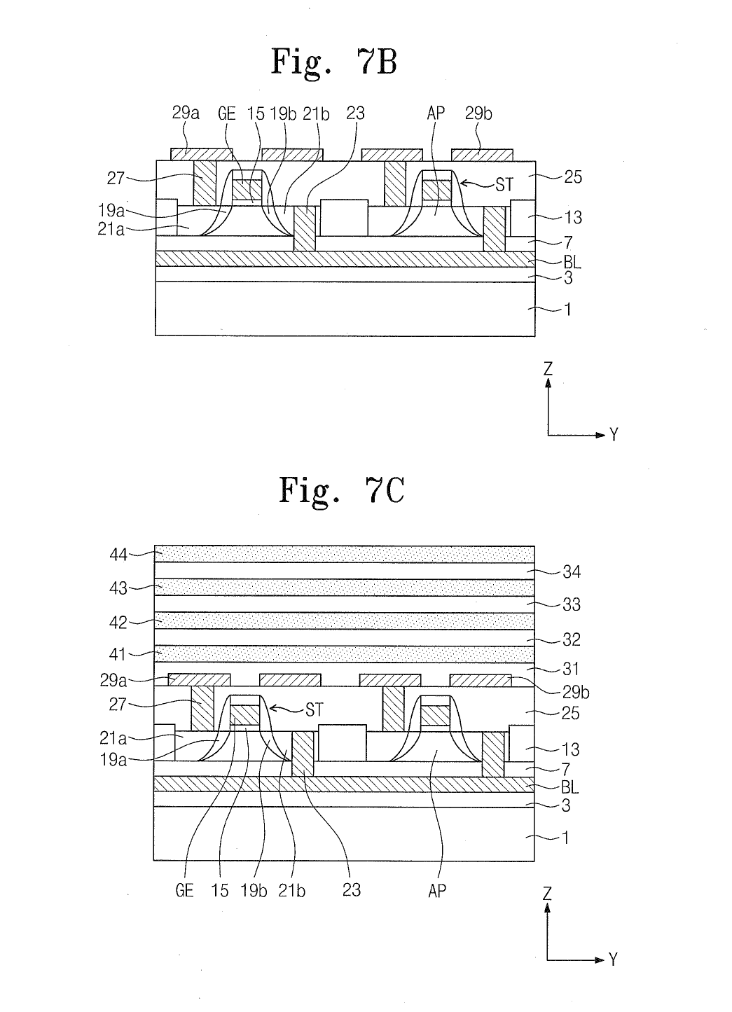

Referring to FIGS. 7A and 7B, a conductive layer may be formed on the third insulating layer 25 and then the conductive layer may be patterned to form first pads 29a and second pads 29b. The first pads 29a are disposed on the first sub-vertical electrodes 27. The first pads 29a may have island-shapes separated from each other. The second pads 29b may be formed to have a line-shape extended in the first direction X.

Subsequently, referring to FIG. 7C, first to fourth word line-interlayer insulating layers 31, 32, 33, and 34 and first to fourth sacrificial layers 41, 42, 43, and 44 may be alternately stacked on the third insulating layer 25 on which the first and second pads 29a and 29b are formed. The sacrificial layers 41, 42, 43, and 44 may be formed of a material having an etch selectivity with respect to the word line-interlayer insulating layers 31, 32, 33, and 34. For example, the sacrificial layers 41, 42, 43, and 44 may be formed of silicon nitride layers and the word line-interlayer insulating layers 31, 32, 33, and 34 may be formed of silicon oxide layers.

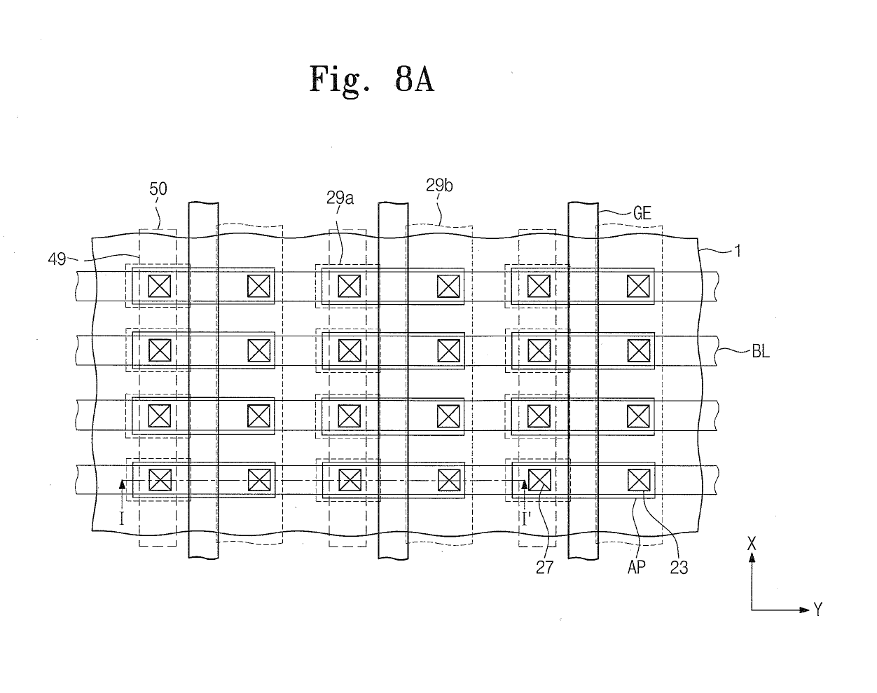

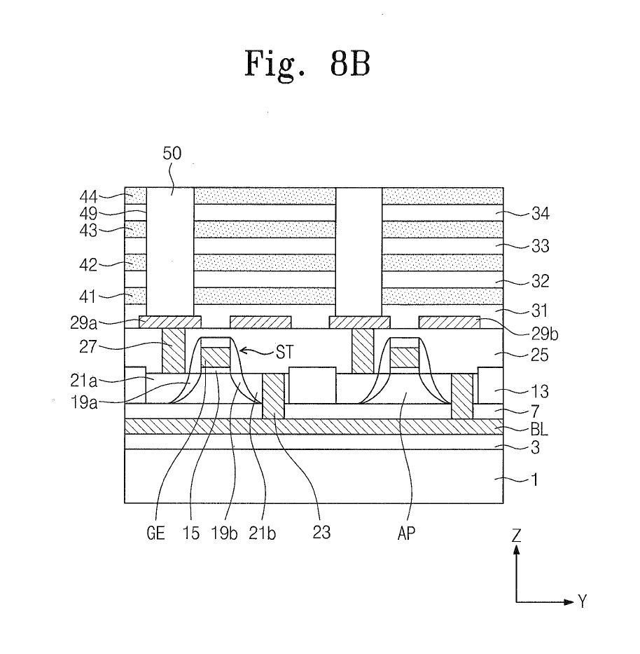

Referring to FIGS. 8A and 8B, the sacrificial layers 41, 42, 43, and 44 and the word line-interlayer insulating layers 31, 32, 33, and 34 may be patterned to form a first grooves 49 extended in the first direction X. The first grooves 49 expose the first pads 29a and the third insulating layer 25. And then a first filling insulating layer 50 may be formed to fill the first grooves 49.

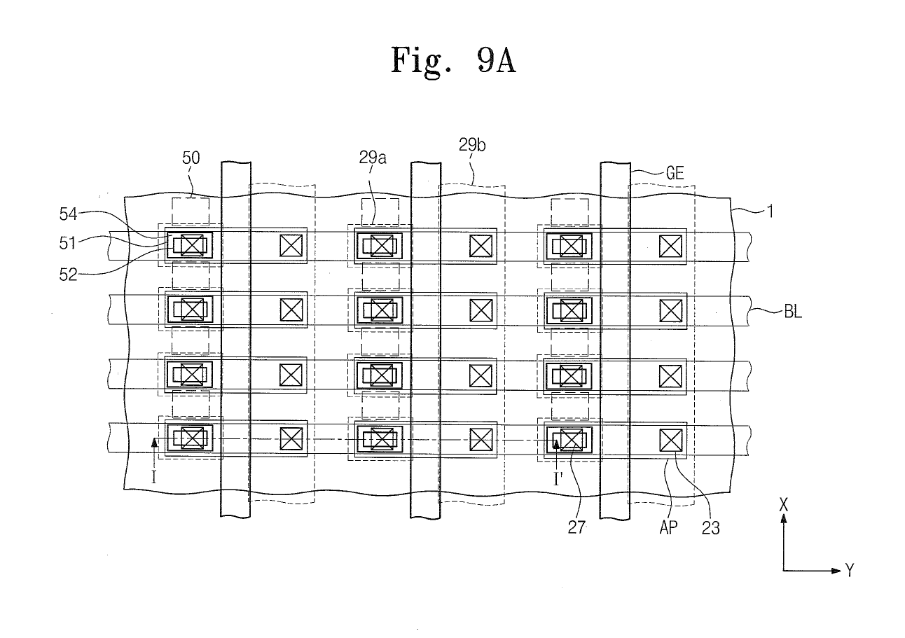

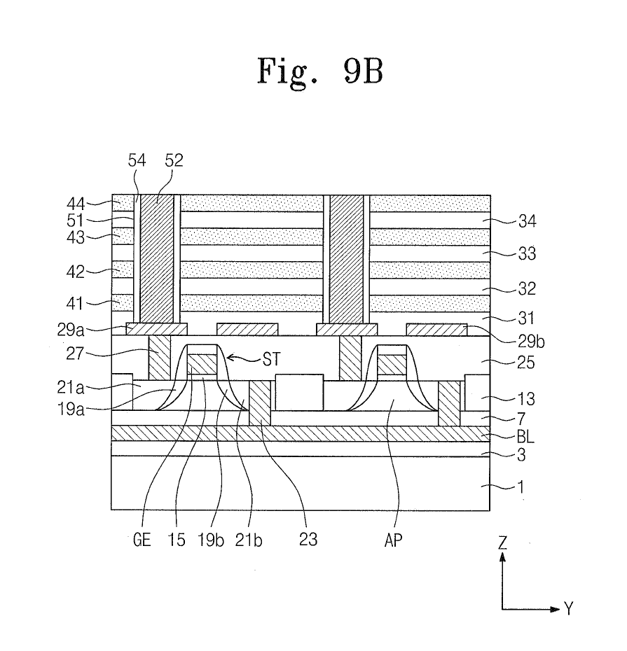

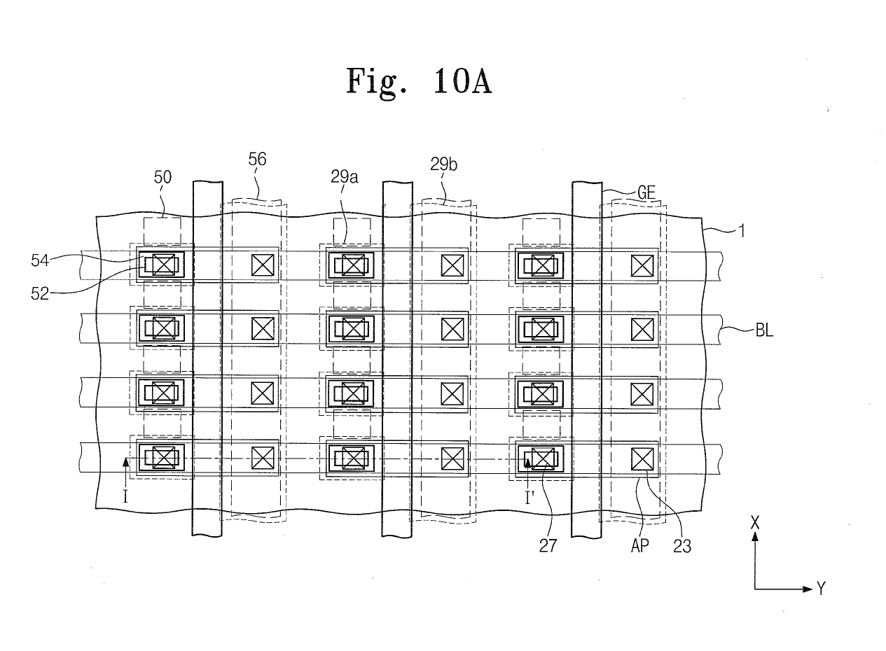

Referring to FIGS. 9A and 9B, the first filling insulating layer 50 may be partially etched to form vertical holes 51 exposing the first pads 29a. The first pads 29a may function as an etch stop layer during the etching process for the formation of the vertical holes 51. A variable resistance layer 54 may be formed to cover an inner sidewall of the vertical holes 51 by a deposition process and an etch-back process. The bottom surface of the vertical hole 51 is exposed.

Subsequently, the vertical holes 51 may be filled with a conductive material, thereby forming second sub-vertical electrodes 52 on the variable resistance layer 54.

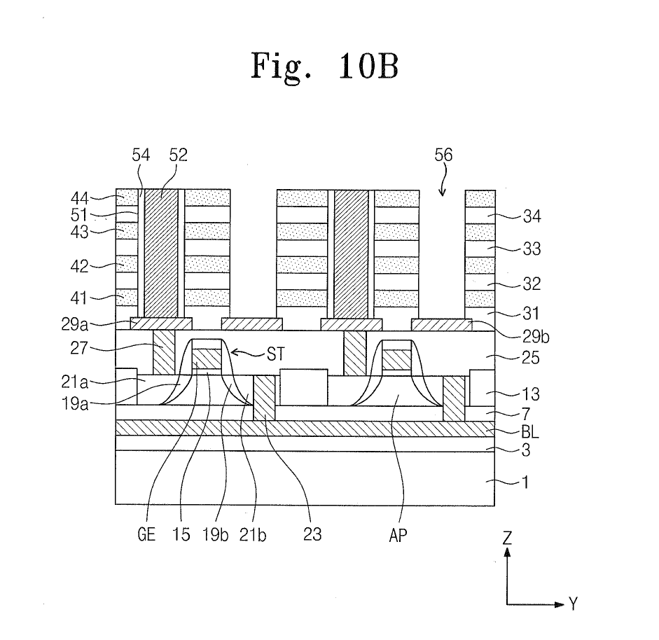

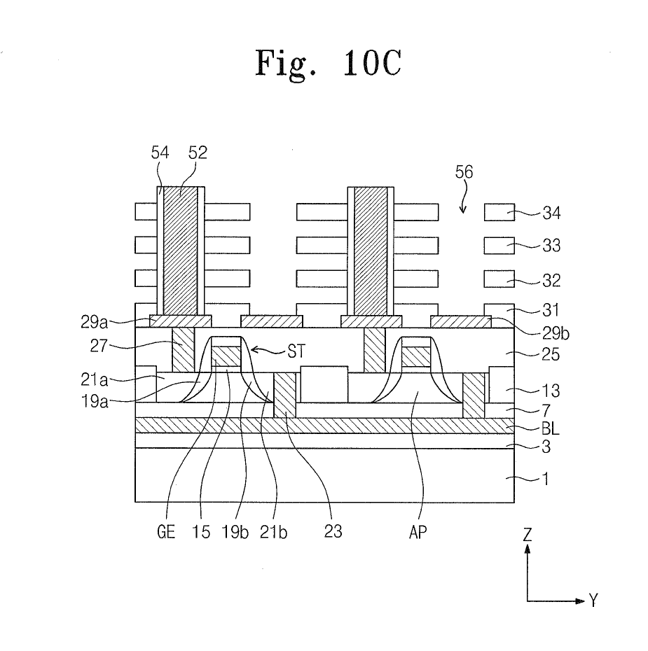

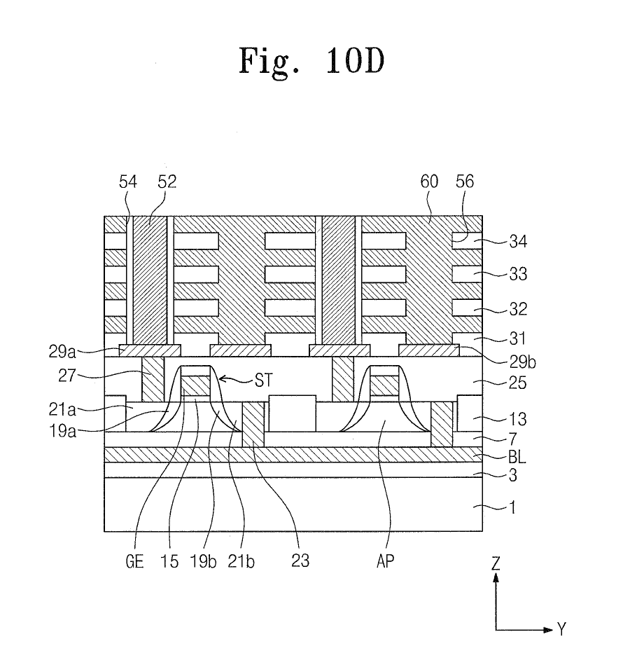

Referring to FIGS. 10A and 10B, second grooves 56 are formed between the second sub-vertical electrodes 52 by patterning the sacrificial layers 41, 42, 43, and 44 and the word line-interlayer insulating layers 31, 32, 33, and 34. The second grooves 56 expose the second pads 29b. The second grooves 56 may have a line-shape extended in the first direction X. The second pads 29b may function as an etch stop layer when the second grooves 56 are formed.

Subsequently, referring to FIGS. 10C and 10D, the sacrificial layers 41, 42, 43, and 44 are replaced with a word line layer 60 through the second grooves 56. In other words, the sacrificial layers 41, 42, 43, and 44 exposed by the second grooves 56 may be selectively removed. And then the word line layer 60 may be formed to fill regions formed by the removal of the sacrificial layers 41, 42, 43, and 44.

Referring to FIGS. 2A and 2B again, the word line layer 60 in the second groove 56 is removed to form word lines WLa1, WLb1, WLa2, WLb2, WLa3, WLb3, WLa4, and WLb4. And then a filling insulating layer 70 is formed in the second groove 56.

According to an embodiment, the process of forming variable resistance memory cells such as forming the variable resistance layer 54 and forming the word lines WLan and WLbn are carried out after the selection transistors ST are formed, avoiding heat budget caused by the high-temperature process of forming the selection transistors ST. Thus, it is possible to maintain characteristic of variable resistance memory cells well.

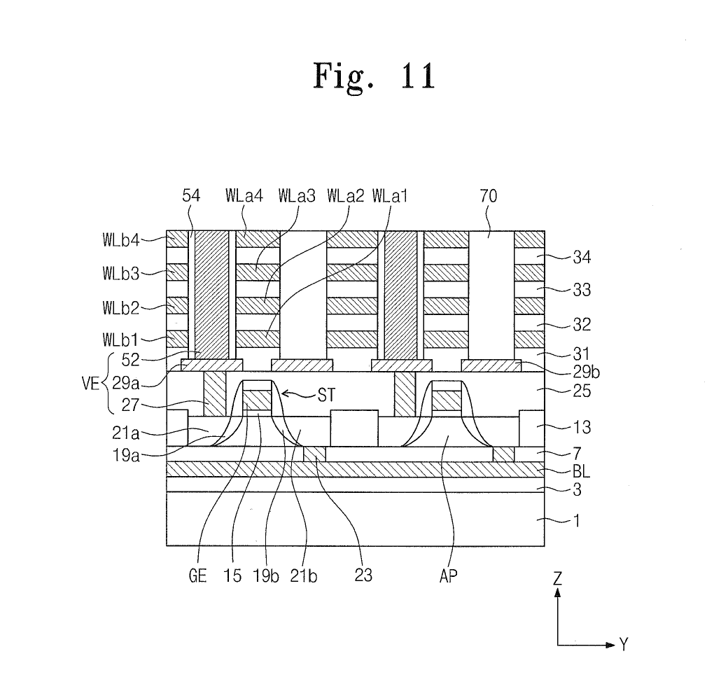

FIG. 11 is a cross-sectional view illustrating a variable resistance memory device according to an embodiment of the inventive concept.

Referring FIG. 11, bit line node contacts 23 may penetrate the second insulating layer 7 and contact with the bottom surface of the second high-concentration injection regions 21b. Other components of the variable resistance memory device except the above point may be substantially the same as or similar to the corresponding components of the variable resistance memory device of FIGS. 2A to 2C.

In a method of forming the variable resistance memory device of FIG. 11, the bit line node contact 23 may be formed in the second insulating layer 7 before the active layer 9 of FIG. 3B is formed. Other processes except this point may be substantially the same as or similar to the corresponding processes of FIGS. 3A to 10D.

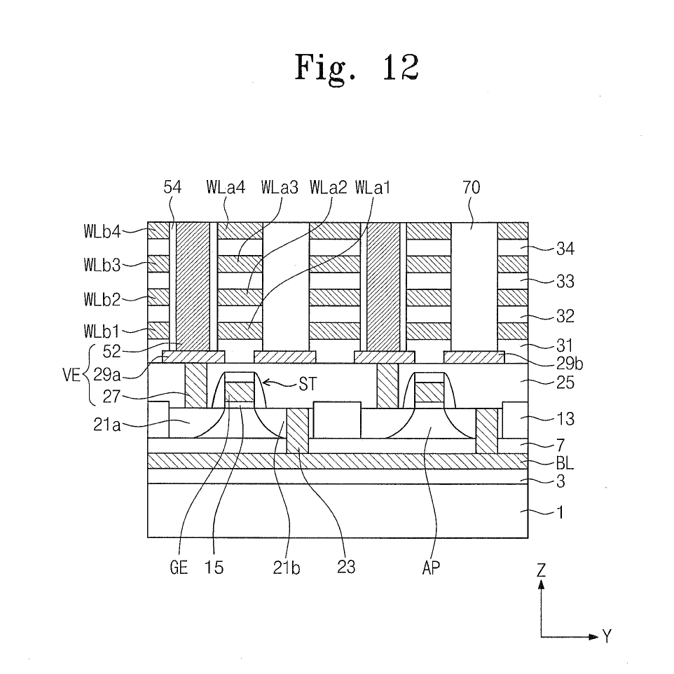

FIG. 12 is a cross-sectional view illustrating a variable resistance memory device according to an embodiment of the inventive concept.

Referring to FIG. 12, the variable resistance memory device does not include the first and second low-concentration dopant injection regions 19a and 19b of FIG. 2B. Other components and formation processes except this point may be substantially the same as or similar to the corresponding components of FIGS. 2A to 2C and formation processes of FIG. 3A to 10D.

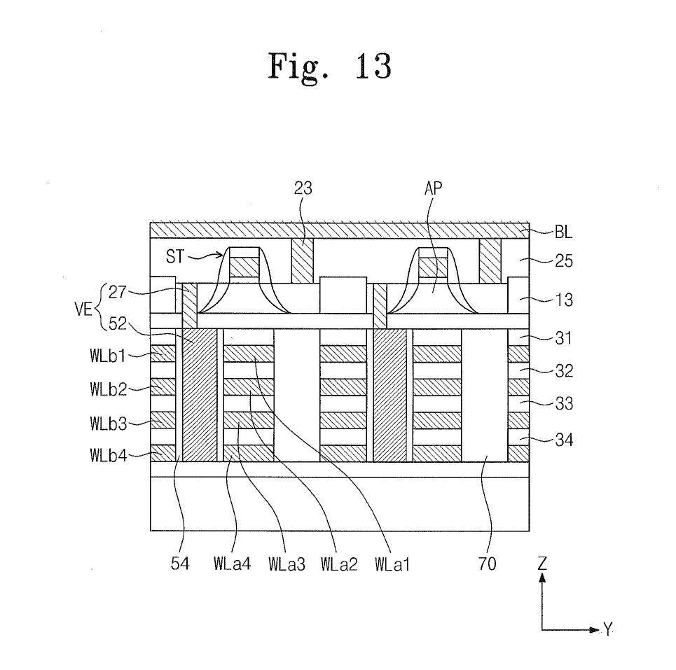

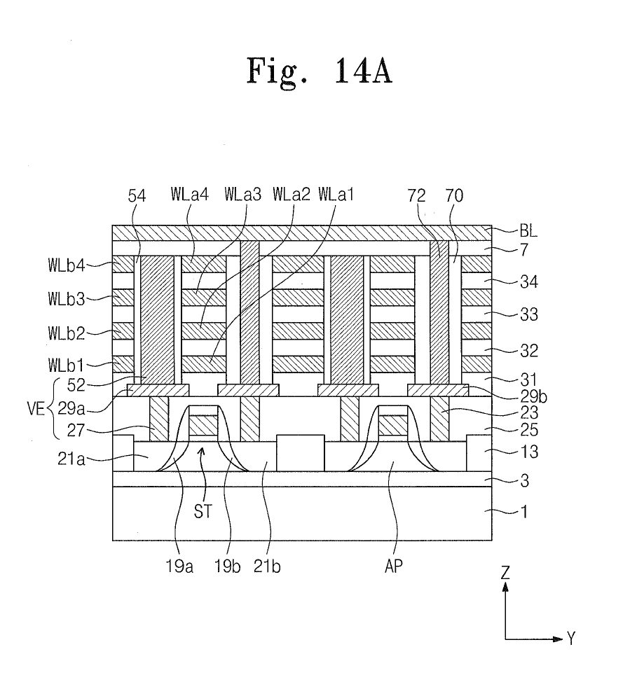

FIG. 13 is a cross-sectional view illustrating a variable resistance memory device according to an embodiment of the inventive concept.

Referring to FIG. 13, active patterns AP, selection transistors ST and bit lines BL may be disposed over the word lines WLa1, WLb1, WLa2, WLb2, WLa3, WLb3, WLa4, and WLb4. Vertical electrodes VE include first and second sub-vertical electrodes 27 and 52. The vertical electrodes VE are aligned vertically with the bit lines BL and disposed under the bit lines. The Vertical electrodes VE do not include the first pads 29a of FIG. 2A. The bit lines BL may be disposed at a level higher than the vertical electrodes VE. Other components and formation processes except this point may be substantially the same as or similar to the corresponding components of FIGS. 2A to 2C and formation processes of FIGS. 3A to 10D.

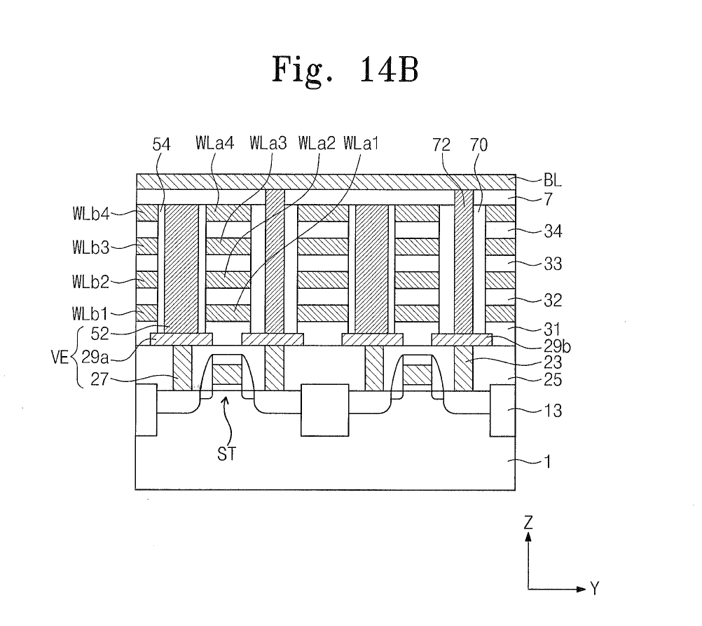

FIGS. 14A and 14B are a cross-sectional view illustrating a variable resistance memory device according to an embodiment of the inventive concept.

Referring to FIG. 14A, a first insulating layer 3 may be disposed on a substrate 1 and active patterns AP may be disposed on the first insulating layer 3. Selection transistors ST are formed at the active patterns AP. The selection transistors ST may be disposed at a level lower than word lines WLa1 and WLb1 in the lowermost floor. Bit lines BL may be disposed at a level higher than vertical electrodes VE. Second pads 29b may have island-shapes separated from each other. The bit lines BL may be electrically connected to the second high-concentration dopant injection regions 21b through first bit line node contacts 23, the second pads 29b, and second bit line node contacts 72. The first bit line node contacts 23 may penetrate a third insulating layer 25 and contact with the second high-concentration dopant injection regions 21b. The second bit line node contacts 72 may penetrate a second insulating layer 7 and a second filling insulating layer 70 and contact with the second pads 29b.

Alternatively, referring to FIG. 14B, the selection transistor ST may be disposed at the substrate 1, not at the active pattern AP.

Other components and formation processes except those described above may be substantially the same as or similar to the corresponding components of FIGS. 2A to 2C and formation processes of 3A to 10D.

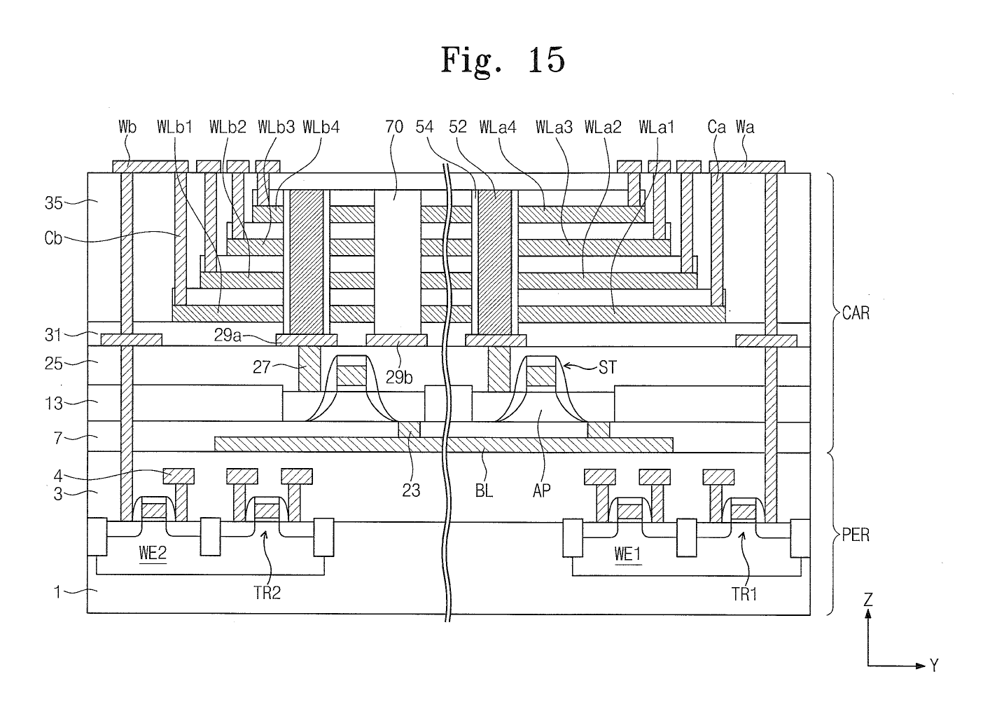

FIG. 15 is a cross-sectional view illustrating a variable resistance memory device according to an embodiment of the inventive concept.

Referring to FIG. 15, the variable resistance memory device includes a peripheral circuit region PER and a cell array region CAR. The peripheral circuit region PER is disposed at a substrate 1 and the cell array region CAR is disposed over the peripheral circuit region PER. The peripheral circuit region PER may include well regions WE1 and WE2 formed in the substrate 1. Peripheral circuit transistors TR1 and TR2 and peripheral circuit interconnections 4 may be formed on the well region WE1 and WE2. A first insulating layer 3 may cover the peripheral circuit transistors TR1 and TR2 and the peripheral circuit interconnections 4.

A cell array of the cell array region CAR may be disposed on the first insulating layer 3. The cell array may have one of structures of the variable resistance memory devices described above. End portions of the word lines WLa1, WLb1, WLa2, WLb2, WLa3, WLb3, WLa4, and WLb4 may constitute a stepped structure. A fourth insulating layer 35 may cover sidewalls of the end portions of the word lines WLa1, WLb1, WLa2, WLb2, WLa3, WLb3, WLa4, and WLb4. The odd-numbered word lines WLan of each cell layer may be connected to first contacts Ca, and the first contacts Ca may be electrically connected to a first transistor TR1 of the peripheral circuit region PER through a first interconnection Wa. Thus, the odd-numbered word lines WLan of each cell layer may be electrically connected to the first transistor TR1. The even-numbered word lines WLbn of each cell layer may be connected to second contacts Cb, and the second contacts Cb may be electrically connected to a second transistor TR2 of the peripheral circuit region PER through second interconnection Wb. Thus, the even-numbered word lines WLbn of each cell layer may be electrically connected to the second transistor TR2. The peripheral circuit region PER may include an X-decoder region and/or a Y-decoder region. The peripheral circuit region PER may include high-voltage transistors. Thus, the peripheral circuit region PER may be formed directly on the substrate 1, so that operation performance of the peripheral region PER may be improved.

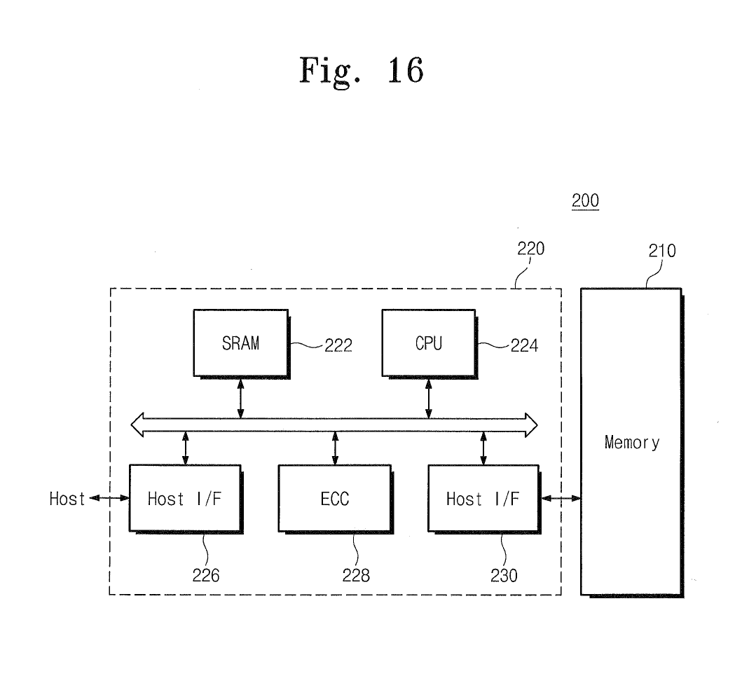

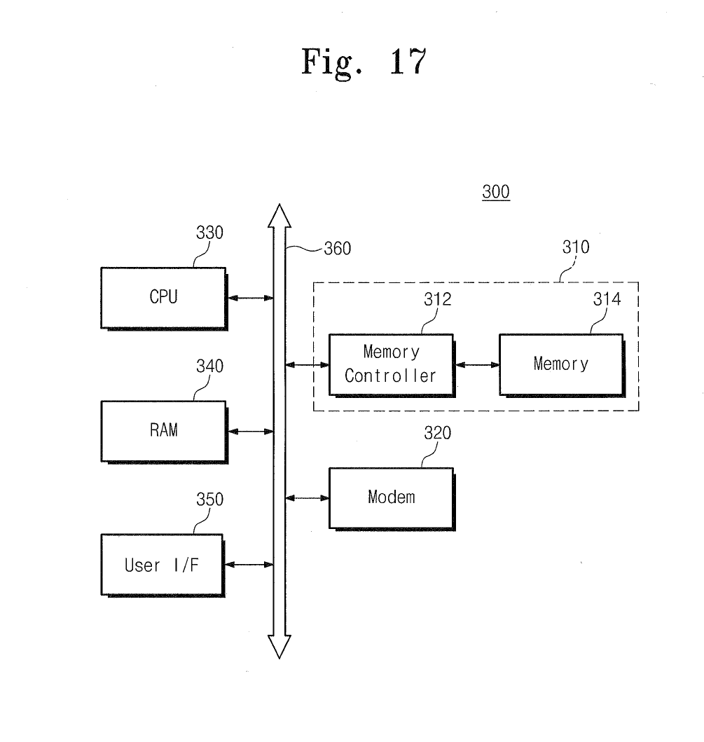

FIG. 16 is a schematic block diagram illustrating a memory card including the variable resistance memory device of the embodiments described above.

Referring to FIG. 16, a memory card 200 includes the variable resistance memory device 210 and a memory controller 220. The memory controller 220 controls data communication between a host and the variable resistance memory device 210. A SRAM 222 may be used as an operation memory of a central processing (CPU) unit 224. A host interface unit 226 may be configured to include a data communication protocol of the host connected to the memory card 200. An error check and correction (ECC) block 228 checks and corrects errors of data which are read out from the variable resistance memory device 210. A memory interface unit 230 is interfaced with the variable resistance memory device 210. The CPU unit 224 controls overall operations for data communication of the memory controller 2220.

FIG. 17 is a schematic block diagram illustrating an information processing system including the variable resistance memory device of embodiments described above.

Referring to FIG. 17, an information processing system 300 may include a memory system 310 including the variable resistance memory device of the embodiments described above. The information processing system 300 may include a mobile device or a computer. For example, the information processing system 300 may include a modulator-demodulator (MODEM) 320, a central processing unit (CPU) 330, a random access memory (RAM) device 340 and a user interface unit 350 that are electrically connected to the memory system 310 through a data bus 360.

The memory system 310 may store data processed by the CPU 330 or data transmitted from an external system. The memory system 310 may include a variable resistance memory device 312 and a memory controller 314. The memory system 310 may have substantially the same configuration as the memory card 200 of FIG. 16. The information processing system 300 may be applied to a memory card, a solid state disk (SSD), a camera image sensor, or other application chipset. In an embodiment, the memory system 310 may include a solid state drive (SSD). In this case, the information processing system 300 may stably and reliably store massive data in the memory system 310.

According to embodiments of the inventive concept, the vertical electrodes may be vertically aligned with the bit lines. The vertical electrodes may be disposed over the bit lines. Alternatively, the vertical electrodes may be disposed under the bit lines. As a result, the planar area of the memory cell may be reduced, so that the variable resistance memory device with high integration density may be realized.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A variable resistance memory device comprising:
a bit line extended in a first direction;
a vertical electrode extended vertically in a third direction and configured to be vertically aligned with the bit line;
a variable resistance layer disposed on a part of the vertical electrode;
multiple word lines disposed on the variable resistance layer and stacked in the third direction, wherein each of multiple word lines are extended in a second direction; and
a selection transistor including a first dopant injection region electrically connected to the vertical electrode and a second dopant injection region electrically connected to the bit line.

2. The variable resistance memory device of claim 1, further comprising:
an active pattern disposed over the bit line, wherein the first dopant injection region and the second dopant injection region are disposed in the active pattern; and
a bit line node contact disposed on the bit line, being electrically connected with the second dopant injection region.

3. The variable resistance memory device of claim 2, wherein the vertical electrode includes a first sub-vertical electrode disposed on the first dopant injection region, a first pad disposed on the first sub-vertical electrode and a second sub-vertical electrode disposed on the pad.

4. The variable resistance memory device of claim 3, further comprising:
a second pad disposed over the bit line node contact wherein the second pad has a line shape extended in the first direction.

5. The variable resistance memory device of claim 2, wherein the bit line node contact is configured to penetrate the active pattern and has a top surface substantially coplanar with a top surface of the active pattern.

6. The variable resistance memory device of claim 2, wherein the bit line node contact is configured to be in contact with a bottom surface of the active pattern.

7. The variable resistance memory device of claim 1, further comprising:
an active pattern disposed under the bit line, wherein the first dopant injection region and the second injection region are disposed in the active pattern; and
a bit line node contact disposed on the second dopant injection region, electrically being connected with the bit line.

8. The variable resistance memory device of claim 7, wherein the active pattern is disposed over the multiple word lines and the vertical electrode includes a first sub-vertical electrode and a second sub-vertical electrode, the first sub-vertical electrode penetrating the first dopant injection region and a second sub-vertical electrode being disposed on the first sub-vertical electrode and adjacent to the multiple word lines.

9. The variable resistance memory device of claim 7, wherein the first and second dopant injection regions are disposed in a substrate, and the bit line node contact includes a first bit line node contact disposed on the second dopant injection region, a second bit line node contact disposed on the first bit line node contact disposed on the bit line, and a second pad connecting the first bit line node and the second bit line node.

10. The variable resistance memory device of claim 7, wherein the multiple word lines are disposed between the bit line and the active pattern, and the bit line node contact includes a first bit line node contact disposed on the second dopant injection region, a second bit line node contact disposed on the first bit line node contact disposed on the bit line, and a second pad connecting the first bit line node and the second bit line node.

11. The variable resistance memory device of claim 1, further comprising:
a peripheral circuit disposed under the vertical electrode and the bit line,
wherein the peripheral circuit controls voltages applied to the word lines, the bit line, and the selection transistor.

12. The variable resistance memory device of claim 1, wherein end portions of the word lines constitute a stepped structure.

13. The variable resistance memory device of claim 1, wherein each of the multiple word lines includes two groups of word lines on a same cell layer and each group of word lines includes a plurality of word lines connected to each other.

14. The variable resistance memory device of claim 1, wherein the selection transistor includes a gate electrode having a line-shape extended in the first direction in a plan view and being disposed over the bit line.

15. The variable resistance memory device of claim 1, wherein the first dopant injection region includes a first low-concentration dopant injection region adjacent to one side of the gate electrode and a first high-concentration dopant injection region separated from the one side of the gate electrode; and
wherein the second dopant injection region includes a second low-concentration dopant injection region adjacent to another side of the gate electrode and a second high-concentration dopant injection region separated from the another side of the gate electrode.

16-20. (canceled)
